(19) United States
(12) Patent Application Publication
(10) Pub. No.: US 2025/0197681 A1
(43) Pub. Date: Jun. 19, 2025

(54) INDIVIDUALIZED PIECE-PROCESSED ADHESIVE FILM, METHOD FOR MANUFACTURING A CONNECTION STRUCTURE, AND CONNECTION STRUCTURE

(71) Applicant: DEXERIALS CORPORATION, Shimotsuke-shi, Tochigi (JP)

(72) Inventors: Yusuke TANAKA, Tochigi (JP); Shogo TAMAGAWA, Tochigi (JP)

(73) Assignee: DEXERIALS CORPORATION, Shimotsuke-shi, Tochigi (JP)

(21) Appl. No.: 18/845,285

(22) PCT Filed: Mar. 17, 2023
(86) PCT No.: PCT/JP2023/010733

§ 371 Date: Sep. 9, 2024

(30) Foreign Application Priority Data
Mar. 31, 2022 (JP) 2022-061428

(51) Int. Cl. C09J 7/20

(52) U.S. Cl. CPC C09J 7/20; C09J 2203/326; C09J 2301/18; C09J 2301/204

(57) ABSTRACT

An individualized piece-processed adhesive film, a method for manufacturing a connection structure, and a connection structure capable of improving adhesive strength with respect to a substrate on which a component is mounted. An individualized piece-processed adhesive film includes individualized pieces having, with respect to a substrate on which a component is mounted, an opening to surround the component, the individualized pieces being arranged in the longitudinal direction of a base material film. A method for manufacturing a connection structure is to connect terminals of the first electronic component to terminals of the second electronic component by using an individualized piece with an opening to surround a component with respect to the substrate on which the component is mounted. This improves the adhesive strength.

### TECHNICAL FIELD

This technology relates to an individualized piece-processed adhesive film in which individualized pieces are arranged in the longitudinal direction of a base material film, a method for manufacturing a connection structure, and a connection structure. This application claims priority based on Japanese Patent Application No. 2022-061428 filed in Japan on Mar. 31, 2022, which is hereby incorporated by reference into this application.

### BACKGROUND ART

Recently, adhesive films such as anisotropic conductive film (ACF), conductive film, and adhesive film (non-conductive film: NCF) are processed into individualized pieces, and a long film in which the individualized pieces arranged in the longitudinal direction of a base material film is wound onto a reel for shipping (e.g., see Patent Document 1).

However, as shown in FIG. 8, in the case of a substrate 100 with a component 101 mounted on the substrate, although it is possible to mount an ACF 103 on a terminal row 102 avoiding the component, full lamination over the entire substrate surface is impossible, resulting in unstable temporary fixing of the component to be connected to the substrate, and the adhesive strength of the resulting connection structure becomes weak. On the other hand, as shown in FIG. 9, in the case of full lamination of the adhesive film provided on the entire surface of the release-treated base material according to the layout of the substrate to avoid the component, ACFs 1031 to 1034 must be pasted, e.g., four times, which increases the required manufacturing steps. In addition, when ACF is laminated multiple times, the lamination error (e.g., ±50 μm) plus the ACF shape error (e.g., ±50 μm on one side) becomes larger, making it difficult to laminate ACF with fewer errors. Even if full lamination could be achieved, there is a concern that productivity would deteriorate to an extreme degree.

### CITATION LIST

### Patent Literature

International Publication No. 2018/066411

### SUMMARY OF INVENTION

### Technical Problem

This technology is proposed in view of such existing circumstances and provides an individualized piece-processed adhesive film, a method for manufacturing a connection structure, and a connection structure capable of improving adhesive strength with respect to a substrate on which a component is mounted.

### Solution to Problem

An individualized piece-processed adhesive film of the present technology includes individualized pieces having, with respect to a substrate on which a component is mounted, an opening to surround the component, the individualized pieces being arranged in the longitudinal direction of a base material film.

A method for manufacturing a connection structure of the present technology uses, with respect to a substrate on which a component is mounted, an individualized piece of adhesive film having an opening to surround the component to connect terminals of the substrate to terminals of an electronic component.

A connection structure of the present technology includes a substrate on which a component is mounted and an electronic component, and terminals of the substrate are connected to terminals of the electronic component by using an individualized piece of adhesive film having an opening to surround the component.

### Advantageous Effects of Invention

According to this technology, the adhesive strength can be improved by using an individualized piece with an opening to surround the component.

### BRIEF DESCRIPTION OF DRAWINGS

FIG. 1 illustrates a first example of an individualized piece-processed adhesive film.

FIG. 2 illustrates a second example of an individualized piece-processed adhesive film.

FIG. 3 illustrates an example of opening design.

FIG. 4 illustrates examples of the shape of the individualized piece with an opening to surround a component with respect to a substrate on which the component is mounted.

FIG. 5 illustrates a first modification of the individualized piece-processed adhesive film.

FIG. 6 illustrates a second modification of the individualized piece-processed adhesive film.

FIG. 7A illustrates a substrate on which a component is mounted, and FIG. 7B illustrates a state in which an individualized piece is pasted to the substrate on which the component is mounted.

FIG. 8 illustrates a conventional ACF lamination method.

FIG. 9 illustrates a conventional method for pasting ACF in a case of full lamination.

### DESCRIPTION OF EMBODIMENTS

Embodiments of the present disclosure will now be more particularly described according to the following order with reference to the accompanying drawings.
1. INDIVIDUALIZED PIECE-PROCESSED ADHESIVE FILM
2. METHOD FOR MANUFACTURING CONNECTING STRUCTURE

### 1. Individualized Piece-Processed Adhesive Film

The individualized piece-processed adhesive film of this embodiment includes individualized pieces having, with respect to a substrate on which a component is mounted, an opening to surround the component, the individualized pieces being arranged in the longitudinal direction of a base material film. This allows full lamination (almost no gap between the individualized piece adhesive film and the mounting plane of the component to be mounted) to the entire surface of the substrate or to the required area, avoiding the component, thereby stabilizing temporary fixing to the component to be connected to the substrate and improving the adhesive strength of the connection structure.

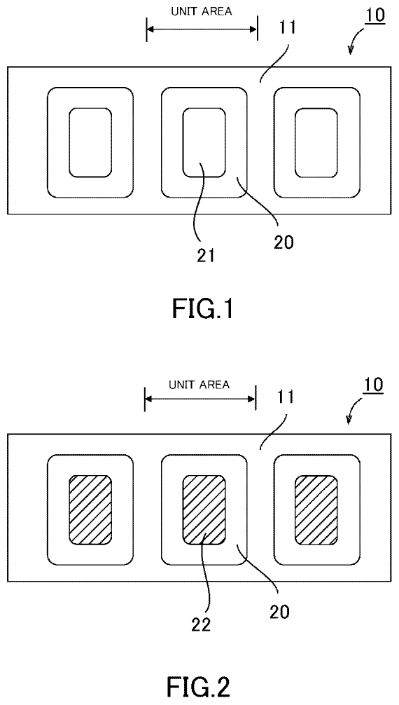

FIG. 1 illustrates a first example of an individualized piece-processed adhesive film, and FIG. 2 illustrates a second example of an individualized piece-processed adhesive film. As shown in FIGS. 1 and 2, the individualized piece-processed adhesive film 10 includes a long base material film 11 and individualized pieces 20 of adhesive film arranged in the longitudinal direction of the base material film 11. The lower limit of the pitch (distance between individualized pieces) of the individualized pieces arranged in the longitudinal direction of the base material film 11 is preferably 0.1 mm or more, more preferably 0.2 mm or more, still more preferably 0.3 mm or more, and the upper limit of the pitch of the individualized pieces is preferably 10 mm or less, more preferably 2 mm or less, still more preferably 1 mm or less.

The individualized piece 20 has, with respect to a substrate on which the component is mounted, an opening to surround the component. The opening may be an exposed portion 21 where the base material film 11 is exposed by half cutting the base material film 11, as shown in FIG. 1, or a void portion 22 where the base material film 11 is not present by full cutting the base material film 11, as shown in FIG. 2.

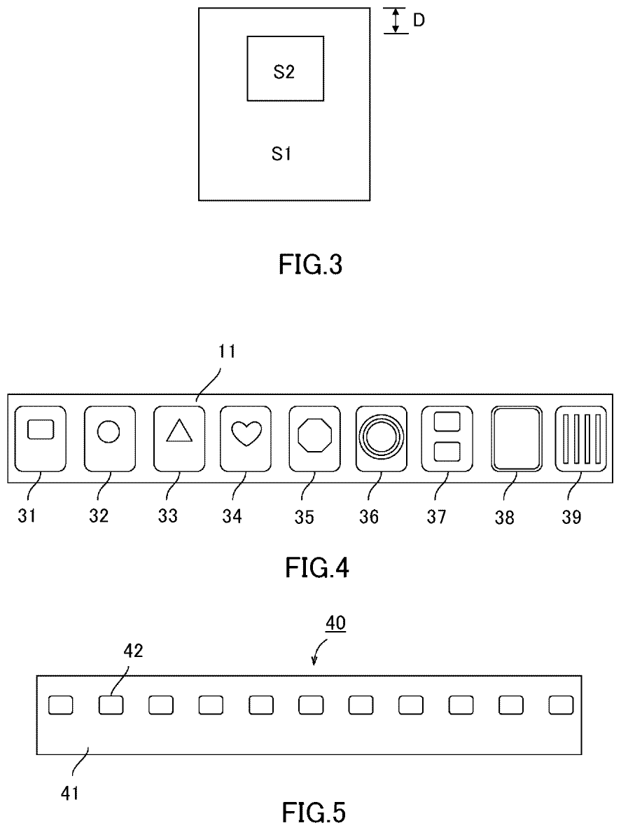

FIG. 3 illustrates an example of opening design. The lower limit of the minimum distance D from the end of the individualized piece to the opening is preferably 0.1 mm or more, more preferably 0.2 mm or more, still more preferably 0.3 mm or more, and the upper limit of the minimum distance D from the end of the individualized piece to the opening is preferably 100 mm or less, more preferably 20 mm or less, still more preferably 10 mm or less.

The lower limit of the area S2 of the opening is preferably 0.01 mm² or more, more preferably 0.04 mm² or more, still preferably 0.09 mm² or more, and the upper limit of the area S2 of the opening is preferably 400 mm² or less, more preferably 225 mm² or less, still more preferably 100 mm² or less. The lower limit of the ratio of the area of the opening S2 to the area of the individualized pieces S1 (S1:S2) is preferably 40,000:1 or more, more preferably 10,000:1 or more, still more preferably 4,000:9 or more, and the upper limit of S1:S2 is preferably 400:392.04 or less, more preferably 16:9 or less, and still more preferably 4:1 or less.

The individualized piece-processed adhesive film 10 is preferably provided with an edge area consisting of the base material film 11 at the edge in the width direction. The length W in the width direction of the edge area consisting of the base material film 11 is preferably 100 μm or more, more preferably 500 μm or more, and still more preferably 1,000 μm or more. The presence of such an edge area makes it difficult for adhesive to protrude from the film, which tends to occur when the film is long. This is because it is difficult for the adhesive to reach the edge of the base material film, thus preventing so-called blocking, which improves practical convenience. As described below, blocking is less likely to occur when the individualized piece is far from the edge of the base material film, which also contributes to productivity.

The individualized piece-processed adhesive film 10 may be wound on a reel with the individualized pieces 20 continuously arranged in unit areas in the longitudinal direction. Here, the “unit area” is an area having, e.g., a rectangular shape with a predetermined length in the longitudinal direction of the base material and can be considered as an area defined by the centerline between two adjacent individualized pieces and the next centerline between next two adjacent individualized pieces, or an area including one individualized piece sandwiched between the centerlines between the adjacent individualized pieces. The adhesive film can be peeled off and separated from the base material film. In this technology, the adhesive film of the individualized piece has no corresponding support and consists only of a layer of adhesive (although a cover film of approximately the same width as the base material may be laminated thereto).

The base material film 11 is a support film that supports multiple individualized pieces. The base material film 11 may be made of, e.g., polyethyleneterephthalate (PET), oriented polypropylene (OPP), poly-4-methylpentene-1 (PMP), and polytetrafluoroethylene (PTFE), among others. Further, a material in which at least the side of the individualized pieces is release treated with silicone resin can be suitably used as the base material film 11.

The thickness of the base material film 11 is not particularly limited. The lower limit of the thickness of the base material film 11 is preferably 10 μm or more, more preferably 25 μm or more, and still more preferably 38 μm or more from the viewpoint of releasing. The upper limit of the thickness of the base material film is preferably 200 μm or less, more preferably 100 μm or less, still more preferably 75 μm or less, and may be 50 μm or less, because there is concern that excessive pressure may be applied to the adhesive film if too thick. When a cover film is provided on an individualized piece of adhesive film, the thickness of the cover film will be in the same range, but the cover film is preferably thinner than the base material film.

The width of the base material film 11 is also not limited. The lower limit of the width of the base material film 11 is preferably 1 mm or more, more preferably 2 mm or more, and still more preferably 4 mm or more from the viewpoint of winding. The upper limit of the width of the base material film 11 is preferably 500 mm or less, more preferably 250 mm or less, and still more preferably 120 mm or less because of the concern that too large a width may make carrying and handling difficult.

Adhesive films are not limited and may include anisotropic conductive film (ACF), conductive film with conductive particles contained in the adhesive, adhesive film (non-conductive film: NFC), and solder-containing film with solder particles, among others. The binder of the adhesive film can be thermosetting or thermoplastic.

When containing conductive particles such as metal particles, resin core metal-coated particles, and solder particles, the individualized pieces may have areas that contain conductive particles and areas that do not contain conductive particles. The individualized pieces may be composed of two or more layers, two or more laminated layers composed of layers containing conductive particles or solder particles and layers not containing conductive particles, two or more mutually laminated layers composed of layers containing conductive particles, or two or more mutually laminated layers composed of layers not containing conductive particles. The binder of the adhesive film can be thermosetting or thermoplastic. It may be a single layer or laminated in multiple layers.

Although the thickness of the individualized pieces is not particularly limited, the lower limit of the individualized piece thickness is preferably 1 μm or more, more preferably 3 μm or more, and still more preferably 4 μm or more, because the base material is easily damaged during processing if too thin, and the upper limit of the individualized piece thickness is preferably 50 μm or less, more preferably 20 μm or less, and still more preferably 10 μm or less because it becomes difficult to punch out the window frame portion during processing if too thick.

The thickness of the individualized pieces can be measured using a known micrometer or digital thickness gauge (e.g., 0.0001 mm minimum indication). However, if the thickness of the individualized pieces is thinner than the particle diameter of the conductive particles, a contact-type thickness gauge is not suitable, so a laser displacement gauge (e.g., spectral interference displacement type) is preferred. Here, the thickness of an individualized piece is the thickness of the binder resin layer only and does not include the particle diameter of the conductive particles.

### Modification 1

FIG. 4 illustrates examples of the shape of the individualized piece with an opening to surround a component with respect to a substrate on which the component is mounted. The shape of the opening may be, e.g., a rectangle as in individualized piece 31, a circle as in individualized piece 32, a triangle as in individualized piece 33, a heart shape as in individualized piece 34, or an octagon as in individualized piece 35. The lower limit of the size (dimension) of the opening is preferably 100 μm or more.

The shape of the opening may alternate between an adhesive film portion and a void portion, as in individualized piece 36, for example. In this case, the minimum width of the adhesive film portion is preferably 100 μm or more. The number of openings in the opening may be two or more, as in individualized piece 37, for example. When the opening is large, as in individualized piece 38, e.g., the minimum width of the adhesive film portion is preferably 100 μm or more. In addition, the width of the opening is preferably 100 μm or more, as in the case of individualized piece 39, e.g., and there may be multiple openings. The opening as described above can penetrate the base material film, but when the adhesive film portion and the void portion alternate as in individualized piece 36, it is preferable not to penetrate the base material film to prevent the adhesive film portion from falling apart.

The individualized pieces may also have other shaped portions in addition to the opening to surround the component. For example, it may have a rectangular U-shape with two horizontal sides and one vertical side, J-shape, L-shape, U-shape, and C-shape, among others, as described, e.g., in JP 2020-198422 A. When containing conductive particles, the conductive particles may be embedded in insulating resin, as described in Japanese Patent No. 6187665. The conductive particles may be randomly or regularly arranged, and the conductive particles are preferably aligned in the film thickness direction. When containing solder particles, as described in Japanese Patent No. 6898413, a thermoplastic resin, which is solid at room temperature and has a melt flow rate of 10 g/10 min or higher when measured at a temperature of 190° C. and a load of 2.16 kg, is preferably blended to achieve a thickness of 50% to 300% of the average particle of the solder particles, and as described in Japanese Patent No. 7032367, the minimum melt viscosity of the adhesive film is preferably less than 100 Pa*s. The binder of the adhesive film can be thermosetting or thermoplastic. It may be a single layer or laminated in multiple layers.

### Modification 2

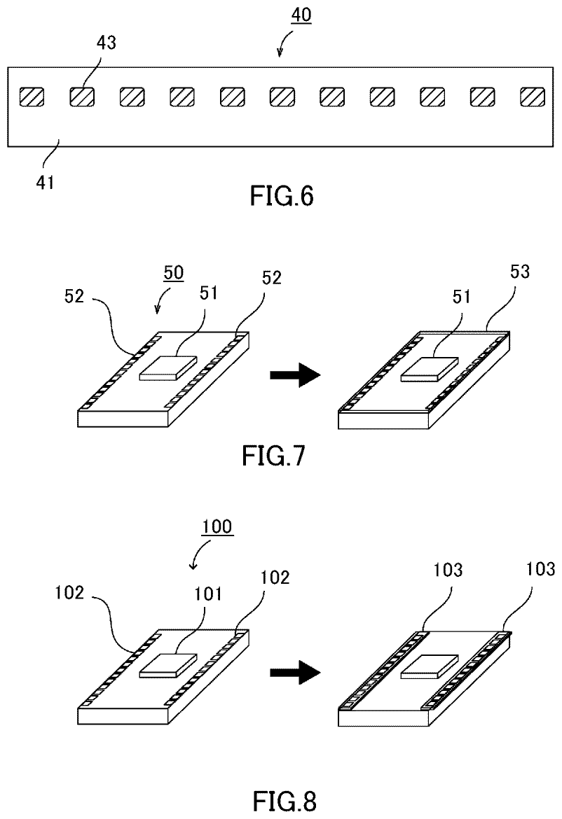

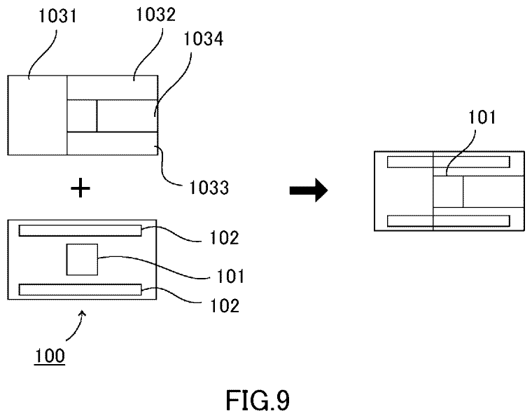

FIG. 5 illustrates a first modification of the individualized piece-processed adhesive film, and FIG. 6 illustrates a second modification of the individualized piece-processed adhesive film. As shown in FIGS. 5 and 6, the individualized piece-processed adhesive film 40 may have openings at predetermined intervals in the longitudinal direction of the adhesive film 41. This allows the base material film to be half-cut to form individualized pieces when the individualized piece-processed adhesive film is used.

The opening may be an exposed portion 42 where the base material film is exposed by half-cutting the base material film, as shown in FIG. 5, or a void portion 43 where the base material film is not present by full-cutting the base material film, as shown in FIG. 6. The base material film may also have half-cuts formed when the individualized piece adhesive film is made.

According to the aforementioned individualized piece-processed adhesive film, since the individualized pieces with an opening to surround the component are arranged in the longitudinal direction of the base material film with respect to the substrate on which the component is mounted, full lamination can be performed on the entire surface of the substrate avoiding the component, thereby stabilizing temporary fixing to the component to be connected to the substrate and improving the adhesive strength of the connection structure. If only the adhesive films provided on the entire surface of the base material film are used, the variety of film widths increases depending on the layout of the connecting component, the equipment of the connecting devices becomes more complex due to the increase in the directions in which the films are pasted, and the process of pasting the film to the substrate becomes more complicated, resulting in higher costs. This technology improves productivity at the time of connection by processing openings in advance for a component (substrate) with a non-flat connection surface that would deteriorate productivity if the adhesive film is applied to one surface at one time (so-called “solid pasting”); the opening-processed adhesive film can be used for other purposes (e.g., reducing unnecessary resin material by storing it on the supply side for management purposes), which is an environmentally friendly practice.

In addition, by providing the opening in the adhesive film individualized pieces, it is possible to provide individualized pieces of a shape more in line with the customer's design and to laminate the individualized pieces more stably and with fewer manufacturing steps. In addition, since the individualized piece can be mounted so as to avoid the component portion, it can be crimped with the component in place, and the manufacturing process of the connection structure can be designed more flexibly, thereby increasing the degree of freedom.

### 2. Method for Manufacturing Connecting Structure

In this method for manufacturing a connection structure, with respect to a substrate on which a component is mounted, terminals of the substrate and terminals of an electronic component are connected by using an individualized piece with an opening to surround the component. The connection between the terminals of the substrate and the terminals of the electronic component can be made according to the description in JP 2020-198422 A.

FIG. 7A illustrates a substrate on which a component is mounted, and FIG. 7B illustrates a state in which an individualized piece is pasted to the substrate on which the component is mounted. As shown in FIG. 7A, a component 51 is mounted on a substrate 50 that includes terminal rows 52 around the component 51. Examples of the substrate 50 may include, e.g., ceramic substrates, rigid substrates, flexible printed circuits (FPC), glass substrates, plastic substrates, and resin multilayer substrates, and examples of the component 51 may include, e.g., image sensors, integrated circuit (IC) modules, and IC chips. In functional modules such as camera modules, ceramic substrates are sometimes used from the viewpoint of superior electrical and thermal insulation properties. Ceramic substrates have advantages such as excellent dimensional stability when miniaturized (e.g., 1 cm² or smaller).

Next, as shown in FIG. 7B, the opening is aligned with the component 51, and the individualized piece 53 is pasted. For example, a pasting device is used to press down the individualized piece from the base material film side to paste the individualized piece onto the substrate 50 placed on a stage. This allows the component 51 to be positioned in the opening and the adhesive film of the individualized piece 53 to surround the component 51. The individualized piece-processed adhesive film from which the individualized pieces are detached may be wound away as the base material film only.

Next, the terminal row 52 of the substrate 50 is connected to the terminals of the electronic component via the individualized pieces 53. For example, via a buffer material, the terminal rows of the substrate and the electronic component are pressed together by using a crimping tool. In addition, depending on the curing type of the adhesive film of the individualized pieces, heating, light irradiation, or the like is performed to cure the individualized pieces. This can complete a connection structure. Examples of the electronic component may include ceramic substrates, rigid substrates, flexible printed circuits (FPCs), glass substrates, plastic substrates, and resin multilayer substrates.

According to this method for manufacturing the connection structure, full lamination can be performed on the entire surface of the substrate avoiding the component, thereby stabilizing temporary fixing to the component to be connected to the substrate and improving the adhesive strength of the connection structure.

The present technology also encompasses the connection structure obtained in this way. In other words, the connection structure in this embodiment includes a substrate on which a component is mounted and an electronic component, and terminals of the substrate are connected to terminals of the electronic component by using an individualized piece of adhesive film having an opening to surround the component.

### REFERENCE SIGNS LIST

10 individualized piece-processed adhesive film, 11 base material film, 20 individualized piece, 21 exposed portion, 22 void portion, 31 to 39 individualized pieces, 40 individualized piece-processed adhesive film, 41 base material film, 42 exposed portion, 43 void portion, 50 substrate, 51 component, 52 terminal row, 53 individualized piece, 100 substrate, 101 component, 102 terminal row, 103 ACF, 1031 to 1034 ACF

1. An individualized piece-processed adhesive film, comprising individualized pieces having, with respect to a substrate on which a component is mounted, an opening to surround the component, the individualized pieces being arranged in the longitudinal direction of a base material film.

2. The individualized piece-processed adhesive film according to claim 1, wherein the opening is an exposed portion of the base material film.

3. The individualized piece-processed adhesive film according to claim 1, wherein the opening is a void portion where the base material film is not present.

4. The individualized piece-processed adhesive film according to claim 1, wherein the long film is wound on a reel.

5. A method for manufacturing a connection structure, comprising using, with respect to a substrate on which a component is mounted, an individualized piece of adhesive film having an opening to surround the component to connect terminals of the substrate to terminals of an electronic component.

6. A connection structure, comprising a substrate on which a component is mounted, and an electronic component, wherein terminals of the substrate are connected to terminals of the electronic component by using an individualized piece of adhesive film having an opening to surround the component.

7. The individualized piece-processed adhesive film according to claim 2, wherein the long film is wound on a reel.

8. The individualized piece-processed adhesive film according to claim 3, wherein the long film is wound on a reel.
